(19) United States
(12) Patent Application Publication
(10) Pub. No.: US 2022/0293422 A1
(43) Pub. Date: Sep. 15, 2022

(54) SEMICONDUCTOR STRUCTURE AND PREPARATION METHOD FOR SEMICONDUCTOR STRUCTURE

(71) Applicant: CHANGXIN MEMORY TECHNOLOGIES, INC., Hefei City (CN)

(72) Inventors: Zijie WANG, Hefei (CN); Huan XIA, Hefei (CN); Jun WEI, Hefei (CN); Yuanhao GAO, Hefei (CN)

(21) Appl. No.: 17/401,405

(22) Filed: Aug. 13, 2021

Related U.S. Application Data
(63) Continuation of application No. PCT/CN2021/103679, filed on Jun. 30, 2021.

(30) Foreign Application Priority Data
Mar. 11, 2021 (CN) 202110264414.5

(51) Int. Cl. H01L 21/285; H01L 29/40; H01L 29/45

(52) U.S. Cl. CPC H01L 21/28518; H01L 29/401; H01L 29/456

(57) ABSTRACT

A semiconductor structure and a preparation method for a semiconductor structure are provided. The preparation method includes: a substrate is provided; and a first material layer and a second material layer are formed on the substrate, and thermal treatment is performed on the first material layer and the second material layer to convert the first material layer into an ohmic contact layer and convert the second material layer into an ion barrier layer.

### CROSS-REFERENCE TO RELATED APPLICATIONS

This application is a continuation of International Application No. PCT/CN2021/103679, filed on Jun. 30, 2021, which claims priority to Chinese Patent Application No. 202110264414.5, filed on Mar. 11, 2021. The disclosures of International Application No. PCT/CN2021/103679 and Chinese Patent Application No. 202110264414.5 are hereby incorporated by reference in their entireties.

### TECHNICAL FIELD

The present disclosure relates to the technical field of semiconductors, and in particular to a semiconductor structure and a preparation method for a semiconductor structure.

### BACKGROUND

In semiconductor devices, the connection of metals to semiconductors is a critical technology. In general, since work functions of the metal and the semiconductor are quite different, a potential barrier exists therebetween, the contact resistance is large, and a Schottky contact can be formed. Thus, the performance of the device is affected.

In the conventional technology, an ohmic contact may be formed between a metal and a semiconductor by introducing metal silicide with a low work function and increasing a doping concentration of the semiconductor, so that the problem of large contact resistance is solved. Specifically, there are mainly two methods. In method (1), a better ohmic contact between the metal and the semiconductor is formed through titanium and titanium nitride. However, the blocking performances of titanium and titanium nitride against the ions in a heavily doped semiconductor are not good, which can affect reliability of a device as produced. In method (2), the diffusion of ions in the heavily doped semiconductor is blocked by amorphous titanium silicon nitride. However, the contact resistance between the titanium silicon nitride and the semiconductor is high, which also affects performance of the device.

### SUMMARY

According to various embodiments of the present disclosure, a preparation method for a semiconductor structure is provided.

The preparation method for a semiconductor structure may include: a substrate is provided; and a first material layer and a second material layer are formed on the substrate, and thermal treatment is performed on the first material layer and the second material layer to convert the first material layer into an ohmic contact layer and convert the second material layer into an ion barrier layer.

The present disclosure also provides a semiconductor structure. The semiconductor structure may include a silicon substrate and a conductive layer, which may be sequentially formed therebetween with: a titanium silicide layer, formed on the silicon substrate and configured to form an ohmic contact with the silicon substrate; and a titanium silicon nitride layer, formed on the titanium silicide layer and configured to block ions in the silicon substrate from diffusing to the conductive layer.

### BRIEF DESCRIPTION OF THE DRAWINGS

In order to more clearly illustrate the technical solutions in the embodiments of the present disclosure or the prior art, the drawings used in the description of the embodiments of the present disclosure or the prior art will be briefly described below. It is apparent that the drawings in the following description are some embodiments of the present disclosure, and other drawings may be obtained from those skilled in the art according to these drawings without any creative work.

FIG. 1 is a top view of a semiconductor structure manufactured according to the present disclosure.

FIG. 2 is a flowchart of a method according to an embodiment of the present disclosure.

FIG. 3 is a flowchart of a method for forming an ohmic contact layer and an ion barrier layer according to an embodiment of the present disclosure.

FIGS. 4(a) to 4(e) show sectional views of various stages of forming a Bit Line Contact (BLC) plug taken along line A-A′ according to the embodiments shown in FIG. 1.

FIG. 5 is a schematic structure diagram of a second material layer according to an embodiment of the present disclosure.

FIG. 6 is a flowchart of a method for forming an ohmic contact layer and an ion barrier layer according to another embodiment of the present disclosure.

FIGS. 7(a) to 7(f) show sectional views of stages of forming a BLC plug taken along line A-A′ according to the embodiment shown in FIG. 1.

FIG. 8 shows a schematic diagram of performance of a contact resistance according to an embodiment of the present disclosure.

FIG. 9 shows a schematic diagram of blocking performance for ions according to an embodiment of the present disclosure.

### DETAILED DESCRIPTION

For convenience of an understanding of the present disclosure, the present disclosure will now be described more completely hereinafter with reference to the related drawings. Preferred implementations of the present disclosure are illustrated in the accompanying drawings. The present disclosure may, however, be implemented in many different forms which are not limited to the implementations described herein. Rather, these implementations are provided so that the disclosure of the present disclosure will be understood thoroughly and completely.

It should be noted that when an element is referred to as being “fixed” to another element, which means the element may be directly on the other element or there may also be an intermediate element. When an element is considered to be “connected” to another element, which means the element may be directly connected to the other element or there may be an intermediate element simultaneously. The terms such as “vertical”, “horizontal”, “left”, “right”, “upper”, “lower”, “front”, “rear”, and “circumferential” and similar expressions used herein are orientation or position relationships based on the accompanying drawings, and are used only for ease and brevity of illustration and description, rather than indicating or implying that the mentioned apparatus or element must have a particular orientation or must be constructed and operated in a particular orientation. Therefore, such terms should not be construed as limiting of the present disclosure.

Unless defined otherwise, all technical and scientific terms used herein have the same meaning as commonly understood by those skilled in the art to which the present disclosure belongs. The terms used herein in the description of the present disclosure is used for describing the purpose of the specific embodiments only and is not intended to be limiting of the present disclosure. As used herein, the term “and/or” includes any and all combinations of one or more of the associated listed items.

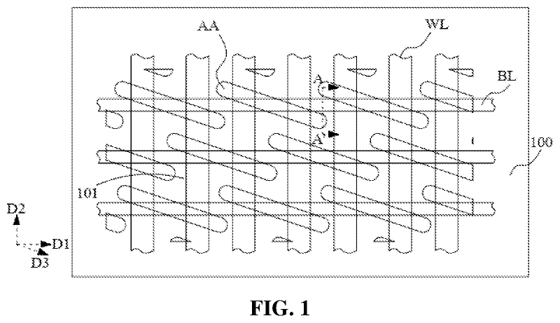

FIG. 1 shows a top view of a semiconductor structure manufactured according to the present disclosure. As shown in FIG. 1, the semiconductor structure has a recessed gate. The semiconductor structure may be configured to form a Dynamic Random Access Memory (DRAM), and includes at least one transistor element and at least one capacitor structure to serve as a minimum constituent unit in a DRAM array and to receive voltage signals from a Bit Line (BL) and a Word Line (WL).

Specifically, the semiconductor structure includes a substrate 100, which may include, for example, a semiconductor substrate formed by silicon. Furthermore, a shallow trench isolation structure 101 is formed in the substrate 100 to define multiple Active Areas (AAs) in the substrate 100, which may be arranged in a staggered array. Specifically, the shallow trench isolation structure 101 includes silicon oxide. Each AA may be in the shape of a long column extending along a third direction D3. The AAs may be arranged parallel to each other. The center of one AA may be adjacent to an end portion of another AA adjacent thereto. In addition, multiple BL structures (including BLs) extending along a first direction D1 and multiple WL structures (including WLs) extending along a second direction D2 are also formed on the substrate 100. Specifically, the BL structures are formed parallel to each other on the substrate 100 and stretch across each AA and the shallow trench isolation structure 101, and the first direction D1 intersects with the third direction D3. The WL structures (i.e., the gates) are formed in the substrate 100 and traverse each AA and the shallow trench isolation structure 101, and the second direction D2 intersects with the third direction D3 and is preferably perpendicular to the first direction D1.

More specifically, a contact plug may be formed on both sides of the WL structure by subsequent processes. For example, the contact plug may include a BLC plug to be electrically connected to source/drain areas (not shown in FIG. 1) of various transistor elements, and may further include a Storage Node Contact (NC) plug to be electrically connected to a capacitor (not shown in FIG. 1).

However, in the existing technology, when the contact plug's connection structure between the metal and the semiconductor is formed, it is generally difficult to make a compromise between the reduction of the contact resistance and the blocking of ion diffusion in the semiconductor, thereby easily affecting the performance of the semiconductor device. Aiming at the foregoing defects, the present disclosure provides an improved preparation method for a semiconductor structure. An ohmic contact layer and an ion barrier layer are formed between the metal and the semiconductor substrate, so that a compromise can be made between the reduction of the contact resistance and the effect of ion blocking.

The preparation method provided by the present disclosure is described below by manufacturing a BL structure after forming the shallow trench isolation structure 101 and WL structure (or buried gate).

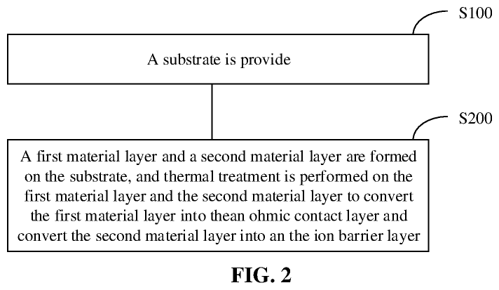

As shown in FIG. 2, the improved preparation method includes operations S100 to 5200.

In operation S100, a substrate is provided.

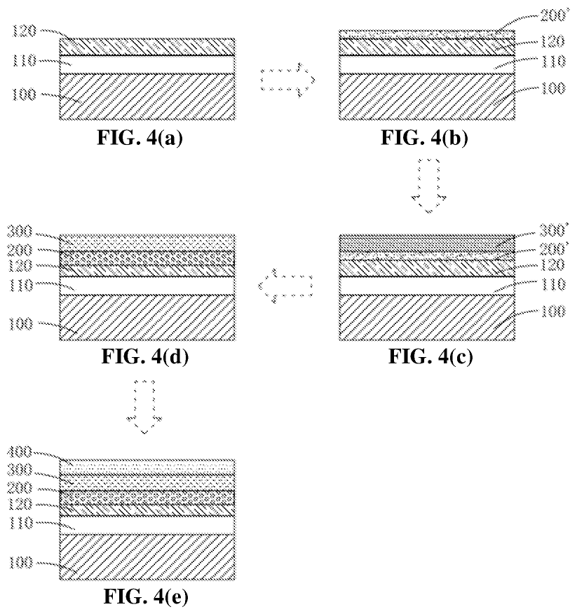

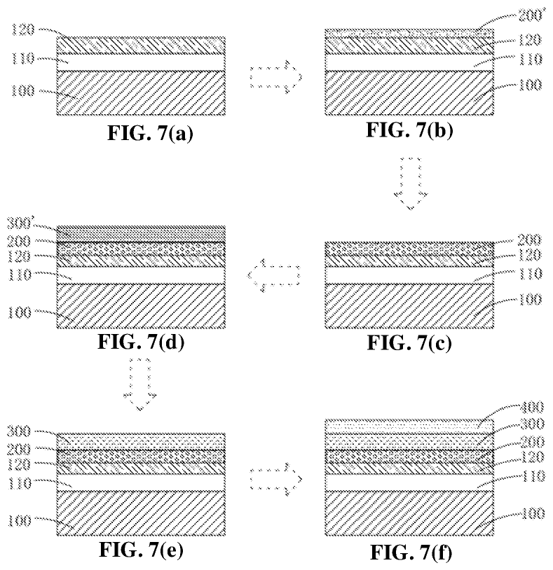

As shown in FIG. 4(a) and FIG. 7(a), the substrate may include a substrate 100, and a silicon oxide layer 110 and a highly-doped poly-silicon layer 120 which are stacked on the substrate 100 by an epitaxial growth process. Specifically, the substrate100 may include a monocrystalline silicon substrate, a Silicon On Insulator (SOI) substrate, a Strained Silicon On Insulator (SSOI) substrate, a Strained Silicon Germanide On Insulator (S-SiGeOI) substrate, a Silicon Germanide On Insulator (SiGeOI) substrate, or a Germanium On Insulator (GeOI) substrate, etc. In the various embodiments of the present disclosure, the substrate 100 includes a monocrystalline silicon substrate.

In operation S200, a first material layer and a second material layer are formed on the substrate, and the thermal treatment is performed on the first material layer and the second material layer to convert the first material layer into the ohmic contact layer and convert the second material layer into the ion barrier layer.

As shown in FIGS. 4 and 7, a first material layer 200′ may be converted into an ohmic contact layer 200 and a second material layer 300′ may be converted into an ion barrier layer 300 by the thermal treatment process. In this way, it facilitates reduction of the diffusion of dopant ions in a semiconductor substrate into a metal while reducing the contact resistance between the metal and the semiconductor substrate, so that the device reliability is improved.

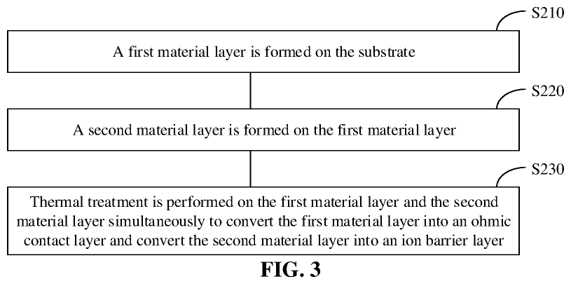

Specifically, in an embodiment, as shown in FIGS. 3 and 4, operation S200 may include operation S210 to S230.

In operation S210, a first material layer is formed on the substrate.

Specifically, as shown in FIG. 4(b), the first material layer 200′ may be formed on the substrate by a deposition process, which may be a physical vapor deposition process.

In operation S220, a second material layer is formed on the first material layer.

Specifically, as shown in FIG. 4(c), the second material layer 300′ may be formed on the first material layer 200′ by a deposition process, which may be an atomic layer deposition process.

In operation S230, the thermal treatment is performed on the first material layer and the second material layer simultaneously to convert the first material layer into an ohmic contact layer and convert the second material layer into an ion barrier layer.

Specifically, as shown in FIG. 4(d), the first material layer 200′ may be reacted with silicon in the substrate to form the ohmic contact layer 200 by at least one thermal treatment process while the second material layer 300′ is converted into the ion barrier layer 300. Therefore, the contact resistance between the metal and the semiconductor is reduced, ions in the semiconductor can be prevented from diffusing to the metal, the performance of the device reliability is improved, the preparation process of the connection structure between the metal and the semiconductor can be simplified, and the preparation cost of the device is reduced.

Furthermore, in operation S210, a titanium layer may be formed as the first material layer 200′ on the substrate by a deposition process. Thus, the titanium layer may be reacted with silicon in the substrate by the thermal treatment process in operation S230 to form a titanium silicide (TiSix) layer as the ohmic contact layer 200. Still furthermore, the deposited titanium layer may have a thickness of 1 nm to 5 nm, e.g., 1 nm, 2 nm, 3 nm, 4 nm, or 5 nm, which is facilitated to achieve a balance between reducing the contact resistance and reducing the height of the BL structure. If the thickness of the titanium layer is less than 1 nm, the formed ohmic contact layer is too thin, and the effect of reducing the contact resistance is not good. If the thickness of the titanium layer is more than 5 nm, the deposited titanium layer is too thick, which is not only disadvantageous for reducing the height of the BL structure, but also causes certain material waste.

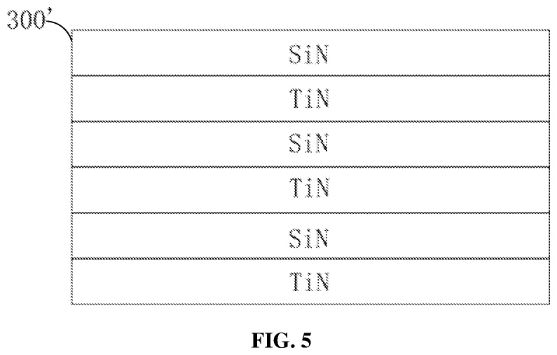

Furthermore, in operation S220, the second material layer 300′ is formed on the first material layer 200′ by the deposition process, and the second material layer 300′ includes multiple titanium nitride layers and silicon nitride layers arranged alternately. Specifically, as shown in FIG. 5, the operation of forming a titanium nitride layer on the first material layer 200′ and the operation of forming a silicon nitride layer on the titanium nitride layer can be performed for multiple cycles, to form multiple titanium nitride layers and silicon nitride layers arranged alternately on the first material layer 200′. Then, the second material layer 300′ is formed into an amorphous titanium silicon nitride (TiSiN) layer as the ion barrier layer 300 by the thermal treatment process in operation S230. Titanium nitride (TiN) or tungsten nitride (WN) or tantalum nitride (TaN) is commonly used as the material of a traditional ion barrier layer. However, because grain boundaries exist among grains of the materials, the barrier effect is poor, boron ions or phosphorus ions in a highly-doped silicon layer are likely to diffuse, and the electrical performance of the device is further affected. Since the titanium silicon nitride layer formed in the present disclosure is amorphous, ions in the highly-doped silicon layer may be effectively blocked from diffusing into the metal, and the device performance is further improved.

Furthermore, the titanium silicon nitride layer formed in operation S230 has a thickness of 1 nm to 5 nm, and may be, e.g., 1 nm, 2 nm, 3 nm, 4 nm, or 5 nm. With this arrangement, it is facilitated to achieve a balance between achieving better ion blocking and reducing the height of the BL structure. When the thickness of the titanium silicon nitride layer is lower than 1 nm, the effect of the ion blocking is reduced. When the thickness of the titanium silicon nitride layer is higher than 5 nm, not only the height of the BL structure is reduced, but also certain material waste is caused.

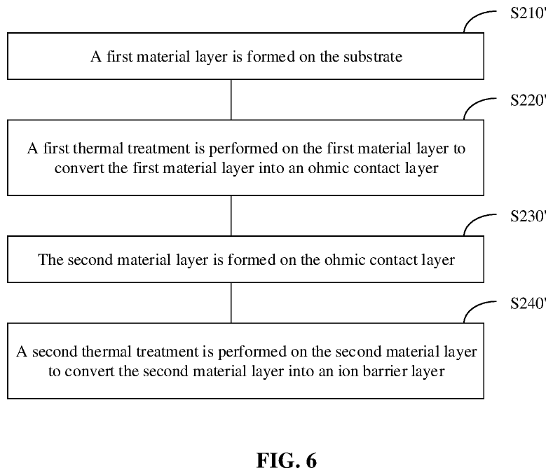

In an embodiment, as shown in FIGS. 6 and 7, operation S200 may include operations S210′ and S220′.

In operation S210′, a first material layer is formed on the substrate.

In operation S220′, a first thermal treatment is performed on the first material layer to convert the first material layer into an ohmic contact layer.

Specifically, as shown in FIGS. 7(b) and (c), a first material layer 200′ may be formed on the substrate by a deposition process, and then the first material layer 200′ may be reacted with silicon in the substrate to form the ohmic contact layer 200 by a first thermal treatment process. Furthermore, a titanium layer may be formed as the first material layer 200′ on the substrate by a physical vapor deposition process. The titanium layer may have a thickness of 1 nm to 5 nm, so that the formed ohmic contact layer 200 is a titanium silicide (TiSix) layer.

In operation S230′, a second material layer is formed on the ohmic contact layer.

In operation S240′, a second thermal treatment is performed on the second material layer to convert the second material layer into an ion barrier layer.

Specifically, as shown in FIGS. 7(d) and (e), a second material layer 300′ may be formed on the ohmic contact layer 200 by a deposition process, and then the second material layer 300′ may be converted into the ion barrier layer 300 by a second thermal treatment process. Furthermore, the second material layer 300′ may include multiple titanium nitride layers and silicon nitride layers arranged alternately. Specifically, the operation of forming a titanium nitride layer on the ohmic contact layer 200 by an atomic layer deposition process and the operation of forming a silicon nitride layer on the titanium nitride layer can be performed for multiple cycles, to form multiple titanium nitride layers and silicon nitride layers arranged alternately as the second material layer 300′ on the ohmic contact layer 200. Then, the multiple titanium nitride layers and silicon nitride layers arranged alternately may be formed into an amorphous titanium silicon nitride (TiSiN) layer as the ion barrier layer 300 by the second thermal treatment process. The titanium silicon nitride layer may have a thickness of 1 nm to 5 nm. The second thermal treatment process is different from the first thermal treatment process. The difference may be embodied in different process temperatures and annealing times, that is, the preparation of the ohmic contact layer 200 and the ion barrier layer 300 can be completed by at least two thermal treatments.

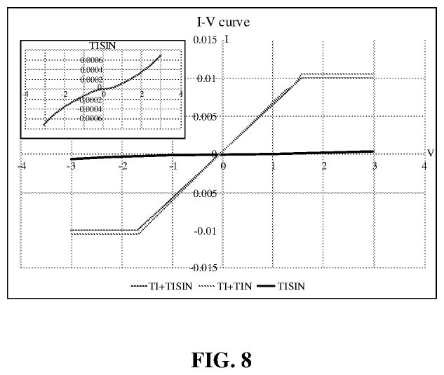

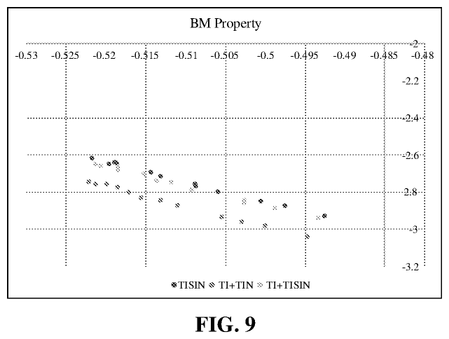

FIGS. 8 and 9 show schematic diagrams of performance of the contact resistance of a BLC plug structure and the performance for ion blocking according to the present disclosure, respectively. As shown in FIG. 8, a metal-semiconductor connection structure, of which a titanium silicide layer is formed using a titanium layer and an amorphous titanium silicon nitride layer is formed using a plurality of titanium nitride layers and silicon nitride layers arranged alternately, may significantly reduce contact resistance, thereby having excellent current-voltage characteristics. In addition, as shown in FIG. 9, the metal-semiconductor connection structure may also obviously reduce the diffusion of dopant ions in a semiconductor into a metal, and has better performance for blocking ions, so that it is beneficial to improve the device performance.

In an embodiment, after operation S200, operations S300 is further included.

In operation S300, a conductive layer is formed on the ion barrier layer.

Specifically, as shown in FIG. 4(e) and FIG. 7(f), a conductive layer 400 is also formed on the ion barrier layer 300 as a bit line (BL) for transmitting an electrical signal. Furthermore, the material of the conductive layer 400 may be tungsten, aluminum, copper, nickel, cobalt, etc. An insulating layer may also be formed on the conductive layer 400 to form insulating protection for the BL, and the material of the insulating layer may be silicon nitride.

It should be noted that the preparation method for a semiconductor structure according to the present disclosure may be applied not only to the manufacture of the foregoing BL structure, but also to a connection structure between other metals and semiconductors. The present disclosure is not limited thereto.

The present disclosure also provides a semiconductor structure. Referring to FIG. 4(e) or FIG. 7(f), the semiconductor structure includes a silicon substrate and a conductive layer 400. The silicon substrate and the conductive layer 400 have therebetween sequentially formed with: a titanium silicide (TiSix) layer 200, formed on the silicon substrate and configured to form an ohmic contact with the silicon substrate; and a titanium silicon nitride (TiSiN) layer 300, formed on the titanium silicide layer 200 and configured to block ions in the silicon substrate from diffusing to the conductive layer.

According to the foregoing semiconductor structure, the titanium silicide layer 200 is formed between the silicon substrate and the conductive layer 400, so that an ohmic contact is formed between the conductive layer 400 and the silicon substrate, so that the contact resistance is reduced. The titanium silicon nitride layer 300 is formed between the silicon substrate and the conductive layer 400, so that the number of ions in the silicon substrate that diffuse to the conductive layer 400 is reduced, thereby improving the device reliability.

In an embodiment, with continued reference to FIG. 4(a) or FIG. 7(a), the substrate may include a substrate 100, and a silicon oxide layer 110 and a highly-doped poly-silicon layer 120 which are stacked on the substrate 100 by an epitaxial growth process. Specifically, the substrate100 may include a monocrystalline silicon substrate, a SOI substrate, a SSOI substrate, a S-SiGeOI substrate, a SiGeOI substrate, or a GeOI substrate, etc. In the various embodiments of the present disclosure, the substrate 100 includes a monocrystalline silicon substrate.

In an embodiment, as shown in FIGS. 4(c) to 4(d) or FIGS. 7(b) to 7(c), the titanium silicide layer 200 may be obtained by performing thermal treatment on a titanium layer 200′ and the silicon substrate. The titanium layer 200′ may be deposited by a physical vapor deposition process, and the thickness may be controlled to be 1 nm to 5 nm, e.g., 1 nm, 2 nm, 3 nm, 4 nm, or 5 nm, which is facilitated to achieve the balance between reducing the contact resistance and reducing the height of a BL structure. If the thickness of the titanium layer 200′ is less than 1 nm, the formed ohmic contact layer is too thin, and the effect of reducing the contact resistance is not good. If the thickness of the titanium layer 200′ is more than 5 nm, the deposited titanium layer is too thick, which is not only disadvantageous for reducing the height of the BL structure, but also causes certain material waste.

Furthermore, the titanium silicon nitride layer 300 may be obtained by performing thermal treatment on multiple titanium nitride layers and silicon nitride layers arranged alternately. Specifically, as shown in FIG. 5, the operation of forming a titanium nitride layer on the titanium layer 200′ or the titanium silicide layer 200 by an atomic layer deposition process, the operation of forming a silicon nitride layer on the titanium nitride layer, and the operation of forming a titanium nitride layer on the silicon nitride layer can be performed for multiple cycles, to form multiple titanium nitride layers and silicon nitride layers arranged alternately. Then, the multi-layer structure may be formed into an amorphous titanium silicon nitride layer 300 by the thermal treatment process. Furthermore, the thickness of the titanium silicon nitride layer may be 1 nm to 5 nm, e.g., 1 nm, 2 nm, 3 nm, 4 nm, or 5 nm. With this arrangement, it is facilitated to achieve a balance between achieving better ion blocking and reducing the height of the BL structure. When the thickness of the titanium silicon nitride layer is lower than 1 nm, the effect of the ion blocking is reduced. When the thickness of the titanium silicon nitride layer is higher than 5 nm, not only the height of the BL structure is reduced, but also certain material waste is caused.

Various technical features of the foregoing embodiments may be randomly combined. For conciseness of description, not all possible combinations of various technical features in the foregoing embodiments are described. However, as long as the combinations of these technical features do not contradict, they should be regarded as falling within the scope of the present specification.

The foregoing embodiments describe only a few implementations of the present disclosure, and the descriptions are specific and detailed, but cannot therefore be construed as limiting of the patent scope of the present disclosure. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

1. A preparation method for a semiconductor structure, comprising:
providing a substrate; and
forming a first material layer and a second material layer on the substrate, and performing thermal treatment on the first material layer and the second material layer to convert the first material layer into an ohmic contact layer and convert the second material layer into an ion barrier layer.

2. The preparation method for a semiconductor structure of claim 1, wherein forming the first material layer and the second material layer on the substrate and performing the thermal treatment on the first material layer and the second material layer comprises:
forming the first material layer on the substrate;
forming the second material layer on the first material layer; and
performing the thermal treatment on the first material layer and the second material layer simultaneously to convert the first material layer into the ohmic contact layer and convert the second material layer into the ion barrier layer.

3. The preparation method for a semiconductor structure of claim 2, wherein the substrate comprises a silicon substrate, and forming the first material layer on the substrate comprises:
forming, on the substrate, a titanium layer as the first material layer by a deposition process.

4. The preparation method for a semiconductor structure of claim 3, wherein the deposition process comprises a physical vapor deposition process.

5. The preparation method for a semiconductor structure of claim 3, wherein the titanium layer has a thickness of 1 nm to 5 nm.

6. The preparation method for a semiconductor structure of claim 3, wherein forming the second material layer on the first material layer comprises:
forming the second material layer on the first material layer by a deposition process, the second material layer comprising a plurality of titanium nitride layers and silicon nitride layers arranged alternately.

7. The preparation method for a semiconductor structure of claim 6, wherein the deposition process comprises an atomic layer deposition process.

8. The preparation method for a semiconductor structure of claim 6, wherein performing the thermal treatment on the first material layer and the second material layer simultaneously to convert the first material layer into the ohmic contact layer and convert the second material layer into the ion barrier layer comprises:
performing the thermal treatment on the first material layer and the second material layer simultaneously, reacting the titanium layer with the silicon substrate to form a titanium silicide layer, and reacting the titanium nitride layer with the silicon nitride layer to form a titanium silicon nitride layer.

9. The preparation method for a semiconductor structure of claim 8, wherein the titanium silicon nitride layer has a thickness of 1 nm to 5 nm.

10. The preparation method for a semiconductor structure of claim 1, wherein forming the first material layer and the second material layer on the substrate and performing the thermal treatment on the first material layer and the second material layer comprises:
forming the first material layer on the substrate;
performing a first thermal treatment on the first material layer to convert the first material layer into the ohmic contact layer;
forming the second material layer on the ohmic contact layer; and
performing a second thermal treatment on the second material layer to convert the second material layer into the ion barrier layer.

11. The preparation method for a semiconductor structure of claim 10, wherein the substrate comprises a silicon substrate, and forming the first material layer on the substrate comprises:
forming, on the silicon substrate, a titanium layer as the first material layer by a deposition process.

12. The preparation method for a semiconductor structure of claim 11, wherein performing the first thermal treatment on the first material layer to convert the first material layer into the ohmic contact layer comprises:
reacting the titanium layer with the silicon substrate by the first thermal treatment to form a titanium silicide layer.

13. The preparation method for a semiconductor structure of claim 10, wherein forming the second material layer on the ohmic contact layer comprises:
forming the second material layer on the ohmic contact layer by a deposition process, the second material layer comprising a plurality of titanium nitride layers and silicon nitride layers arranged alternately.

14. The preparation method for a semiconductor structure of claim 13, wherein performing the second thermal treatment on the second material layer to convert the second material layer into the ion barrier layer comprises:
reacting the titanium nitride layer with the silicon nitride layer by the second thermal treatment to form a titanium silicon nitride layer.

15. The preparation method for a semiconductor structure of claim 1, further comprising: after forming the first material layer and the second material layer on the substrate and performing the thermal treatment the first material layer and the second material layer, forming a conductive layer on the ion barrier layer.

16. The preparation method for a semiconductor structure of claim 2, further comprising: after forming the first material layer and the second material layer on the substrate and performing the thermal treatment the first material layer and the second material layer,
forming a conductive layer on the ion barrier layer.

17. The preparation method for a semiconductor structure of claim 3, further comprising: after forming the first material layer and the second material layer on the substrate and performing the thermal treatment the first material layer and the second material layer,
forming a conductive layer on the ion barrier layer.

18. The preparation method for a semiconductor structure of claim 4, further comprising: after forming the first material layer and the second material layer on the substrate and performing the thermal treatment the first material layer and the second material layer,
forming a conductive layer on the ion barrier layer.

19. A semiconductor structure, comprising a silicon substrate and a conductive layer having therebetween sequentially formed with:
a titanium silicide layer, formed on the silicon substrate and configured to form an ohmic contact with the silicon substrate; and
a titanium silicon nitride layer, formed on the titanium silicide layer and configured to block ions in the silicon substrate from diffusing to the conductive layer.

20. The semiconductor structure of claim 19, wherein the titanium silicon nitride layer has a thickness of 1 nm to 5 nm.
